(19) United States
(12) Patent Application Publication
(10) Pub. No.: US 2025/0174426 A1
(43) Pub. Date: May 29, 2025

(54) OBJECTIVE LENS COVER AND CHARGED PARTICLE BEAM APPARATUS INCLUDING THE SAME

(71) Applicant: KOREA RESEARCH INSTITUTE OF STANDARDS AND SCIENCE, Daejeon (KR)

(72) Inventors: Takashi OGAWA, Daejeon (KR); Jun Hyeok HWANG, Icheon-si (KR)

(73) Assignee: KOREA RESEARCH INSTITUTE OF STANDARDS AND SCIENCE, Daejeon (KR)

(21) Appl. No.: 18/941,597

(22) Filed: Nov. 8, 2024

(30) Foreign Application Priority Data
Nov. 24, 2023 (KR) 10-2023-0165218

(51) Int. Cl. H01J 37/141; H01J 37/244; H01J 37/28

(52) U.S. Cl. CPC H01J 37/141; H01J 37/244; H01J 37/28; H01J 2237/2448

(57) ABSTRACT

Provided are an objective lens cover and a charged particle beam apparatus including the same. The objective lens cover of the charged particle beam apparatus according to an embodiment of the present invention includes a conical cover having a shape corresponding to an external shape of an objective lens, on which the objective lens is mounted, and having an opening through which a charged particle beam passes, and an inner cylindrical part inserted into an inside of the conical cover through the opening and having a beam path through which the charged particle beam passes, wherein the objective lens cover divides at least two regions with a pressure difference of at least 50 times.

### CROSS-REFERENCE TO RELATED APPLICATION

This application claims priority to and the benefit of Korean Patent Application No. 10-2023-0165218, filed on 24 Nov. 2023, the disclosure of which is incorporated herein by reference in its entirety.

### BACKGROUND

### 1. Field of the Invention

The present disclosure generally relates to an objective lens cover and a charged particle beam apparatus including the same.

### 2. Discussion of Related Art

A charged particle beam apparatus is an apparatus that uses a charged particle optical system using electric and magnetic fields to focus a charged particle beam emitted from a particle source on a surface of a sample and irradiate the sample with the charged particle beam. Charged particle beam apparatuses are widely used in the fields of materials science, nanoscience, and electronic engineering. Microscopic observation using a charged particle beam apparatus can achieve high spatial resolution, and thus it is possible to observe even tiny structures that cannot be observed with a general optical microscope, such as thin films grown on a substrate, nanotubes, plasmonic structures, and atomic arrangements of a sample. By irradiating a sample with a charged particle beam and analyzing the energy of the charged particle beam generated from the sample, elements, chemical bonds, and molecular bonds of the sample may be analyzed. Further, the charged particle beam apparatus may observe the microstructure of biological samples such as cells, and may determine the crystal structure of the sample through electron beam diffraction images.

Among charged particle beam apparatuses, a scanning electron microscope (SEM) is an apparatus that forms a microscopic image by focusing and scanning an electron beam emitted from a particle source on a sample and detecting signal electrons.

Magnetic lenses using magnetic fields are mainly used as objective lenses of SEMs. Recently, in order to obtain more information of a surface of a sample in a SEM and prevent the charging of the sample and damage to the sample, it is becoming important to perform observations under low-energy conditions. In addition, since a depth at which electron beams penetrate a sample becomes shallower and a signal at a surface of the sample becomes stronger under low-energy conditions, the analysis of the surface of the sample under low-energy conditions is also becoming important.

### SUMMARY OF THE INVENTION

The present invention is directed to providing an objective lens cover that enable the use of an objective lens located between two regions of ultra-high vacuum (UHV) and high vacuum (HV), and a charged particle beam apparatus including the same.

According to an aspect of the present invention, there is provided an objective lens cover of a charged particle beam apparatus, which includes a conical cover having a shape corresponding to an external shape of an objective lens, on which the objective lens is mounted, and having an opening through which a charged particle beam passes, and an inner cylindrical part inserted into an inside of the conical cover through the opening and having a beam path through which the charged particle beam passes, wherein the objective lens cover divides at least two regions with a pressure difference of at least 50 times.

The conical cover and the inner cylindrical part may be airtightly welded.

The conical cover and the inner cylindrical part may be airtightly connected.

Any one of the two regions may be a sample chamber in which a sample is placed, and the other of the two regions may be an internal region of the objective lens.

Any one of the two regions may be a region maintained at the ultra-high vacuum (UHV) degree of 1×10⁻⁷ Pa or less, and the other of the two regions may be a region maintained at the high vacuum (HV) degree.

The conical cover may be made of a material that does not emit gas into either of the two regions.

The objective lens cover may further include a flange configured to extend outward from the conical cover and having a knife edge, wherein the knife edge is coupled to a sealing member and engaged with any one of the two regions.

The inner cylindrical part may extend to be airtightly sealed with an objective lens cylindrical part, through which the charged particle beam passes, in the objective lens.

The objective lens cover may further include a sealing member, wherein the sealing member may connect the inner cylindrical part to the objective lens cylindrical part to be airtightly sealed.

According to another aspect of the present invention, there is provided a charged particle beam apparatus which includes a charged particle source, one or more condenser lenses configured to focus a charged particle beam, an objective lens configured to irradiate a sample with the charged particle beam, a detector configured to detect secondary electrons formed from the sample, a conical cover having a shape corresponding to an external shape of the objective lens, on which the objective lens is mounted, and having an opening through which the charged particle beam passes, and an inner cylindrical part inserted into an inside of the conical cover through the opening and having a beam path through which the charged particle beam passes, wherein the objective lens cover divides at least two regions with a pressure difference of at least 50 times.

The conical cover and the inner cylindrical part may be airtightly welded.

The conical cover and the inner cylindrical part may be airtightly connected.

Any one of the two regions may be a sample chamber in which the sample is placed, and the other of the two regions may be an internal region of the objective lens.

The sample chamber and the internal region of the objective lens may be maintained at different pressures by separate pumps.

Any one of the two regions may be a region maintained at the UHV degree of 1×10⁻⁷ Pa or less, and the other of the two regions may be a region maintained at a process of 5×10⁻⁶ Pa to 1×10⁻⁴ Pa.

The conical cover may be made of a material that does not emit gas into either of the two regions.

The objective lens cover may further include a flange that extends outward from the conical cover and having a knife edge, and the knife edge may be coupled to a sealing member and engaged with any one of the two regions.

The inner cylindrical part may extend to be airtightly sealed with an objective lens cylindrical part, through which the charged particle beam passes, in the objective lens.

The objective lens cover may further include a sealing member, and the sealing member may connect the inner cylindrical part to the objective lens cylindrical part to be airtightly sealed.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a schematic diagram illustrating an outline of a charged particle beam apparatus according to an embodiment of the present invention;

FIG. 2 is a diagram illustrating pressures in respective elements of the charged particle beam apparatus according to the present embodiment;

FIG. 3 is a diagram illustrating one example of an objective lens cover;

FIG. 4 is a diagram illustrating another example of the objective lens cover;

FIG. 5 is a cross-sectional view illustrating an outline of an inner connection part;

FIG. 6 is a view showing a charged particle beam apparatus equipped with an objective lens cover according to an embodiment of the present invention;

FIG. 7 is a view showing a pressure inside a sample chamber; and

FIGS. 8A and 8B are views showing the degree of contamination of a sample according to a vacuum level inside a sample chamber in scanning electron microscope (SEM) observation.

### DETAILED DESCRIPTION OF EXEMPLARY EMBODIMENTS

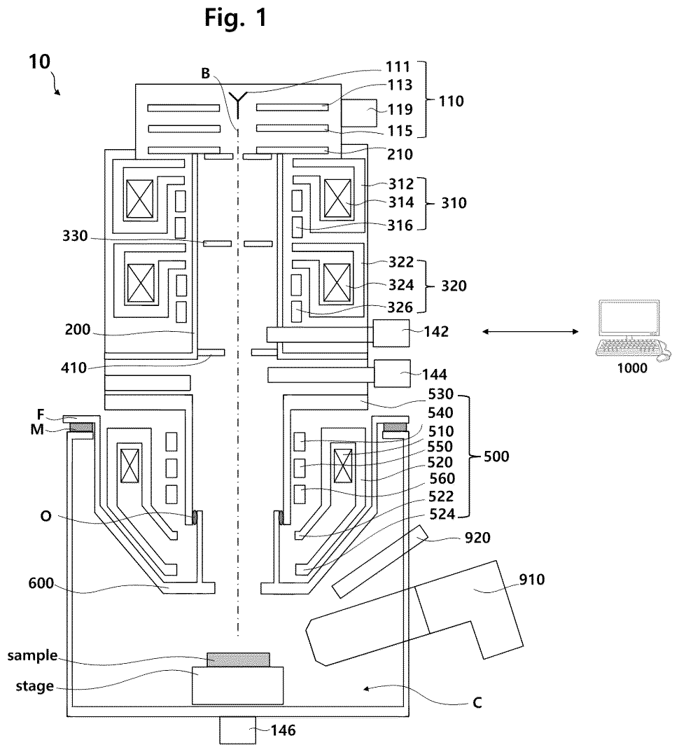

Hereinafter, embodiments of the present invention will be described with reference to the accompanying drawings. FIG. 1 is a schematic diagram illustrating an outline of a charged particle beam apparatus 10 according to an embodiment of the present invention. Referring to FIG. 1, the charged particle beam apparatus 10 according to the present embodiment includes a charged particle source 110, one or more condenser lenses 310 and 320 that focus a charged particle beam B, an objective lens 500 that irradiates a sample with the charged particle beam B, and a secondary electron detector 920 that detects secondary electrons (SEs) and back scattered electrons (BSEs) generated from the sample.

A user accesses the charged particle beam apparatus 10 through a user terminal 1000 and provides commands to control the charged particle beam apparatus 10.

The charged particle beam apparatus 10 illustrated in FIG. 1 is scanning electron microscope (SEM) and includes a spectrometer 910, and the secondary electron detector 920. The SEs and BSEs generated from the sample are incident on the spectrometer 910, and the energy is analyzed to detect elements, chemical bonding states, band transitions, phonons, or molecular vibration states on a surface of the sample. Some of the SEs and BSEs generated from the sample are detected by the secondary electron detector 920.

Referring to FIG. 1, an electron source 110 includes a filament 111, a suppressor electrode 113, an extractor electrode 115, a vacuum pump 119 for an electron source. The vacuum pump 119 for an electron source makes an inside of the electron source 110 be a desired vacuum degree.

The filament 111 generates charged particles. In one embodiment, the filament 111 may be a thermionic emission device that is heated and emits electrons. As a current is applied to the filament 111, the filament 111 is heated and emits electrons. For example, the filament 111 may be made of any one of a lanthanum hexaboride (LaB₆) single crystal, a cerium hexaboride (CeB) single crystal, tungsten coated with zirconia (ZrO—W), and tungsten.

The suppressor electrode 113 prevents the generated charged particles from being emitted as electrons in a random direction, and the extractor electrode 115 extracts the charged particles in a desired direction.

In one embodiment, the charged particle beam apparatus 10 may further include a beam electrode 210 that determines the energy of the charged particle beam B provided from the electron source 110. The beam electrode 210 may be connected to a beam tube 200 that forms a path through which the charged particle beam B passes.

In the illustrated embodiment, the charged particle beam apparatus 10 may include a first condenser lens 310 and a second condenser lens 320, and the first condenser lens 310 is formed by a coil 314 being wound inside a yoke 312 having a gap. A magnetic flux formed by the coil 314 flows out through the gap formed in the yoke 312, and the magnetic flux flowing out from the gap acts as a lens that focuses the charged particle beam B. The charged particle beam B has a beam diameter limited by the first condenser lens 310 and a first aperture 330, and a current of the charged particle beam B is determined. In one embodiment, the first condenser lens 310 may further include an optical axis aligner 316 that controls an optical axis of the first condenser lens 310.

The second condenser lens 320 is formed by a coil 324 being wound inside a yoke 322 having a gap. A magnetic flux formed by the coil 324 flows out through the gap formed in the yoke 322, and the magnetic flux flowing out from the gap acts as a lens that focuses the charged particle beam B. The second condenser lens 320 controls a convergent angle at which the charged particle beam B is focused on the sample. In one embodiment, the second condenser lens 320 may further include an optical axis aligner 326 that controls an optical axis of the second condenser lens 320.

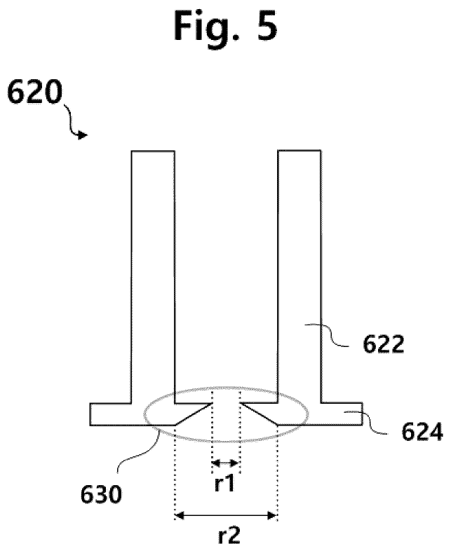

The charged particle beam B that has passed through an orifice 410 for a beam tube in the beam tube 200 enters an inside of the objective lens 500 through an objective lens communication member 530. In the illustrated embodiment, the objective lens communication member 530 may be airtightly connected to an inner wall part 622 (see FIG. 5) of an objective lens cover 600. In the illustrated example, the objective lens communication member 530 may be connected to the inner wall part 622 (see FIG. 5) of the objective lens cover 600 through an O-ring O. For example, the O-ring O may be formed of an elastomer such as a deformable rubber or the like. In another example not illustrated, the objective lens communication member and the inner wall part of the objective lens cover may be welded and airtightly connected.

The objective lens 500 includes two pole pieces 522 and 524 extending from a yoke 520 with a gap therebetween, and a coil 510 wound inside the yoke 520. A magnetic flux formed by the coil 510 flows out through a gap formed between the pole pieces 522 and 524, and the magnetic flux flowing out from the gap acts as a lens that focuses the charged particle beam B.

An objective lens optical axis aligner 540 aligns optical axis of the objective lens 500, and a scanning unit 550 provides the charged particle beam B to the sample while scanning the charged particle beam B. Astigmatism correction is performed by a stigmator 560.

The objective lens cover 600 is located outside the objective lens 500. The objective lens cover 600 may include a flange F, and the flange F may be connected to a sample chamber C through a metal sealing member M so that the sample chamber C is sealed. For example, the flange F may have a surface, which faces the metal sealing member M, being processed with a knife edge to improve airtightness.

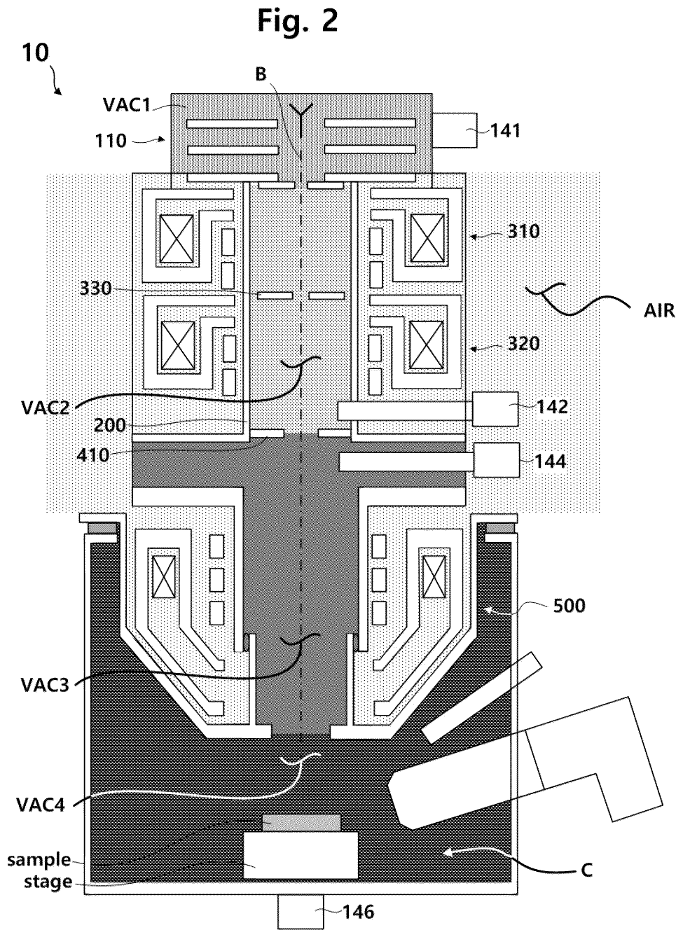

FIG. 2 is a diagram illustrating pressures in respective elements of the charged particle beam apparatus 10 according to the present embodiment. FIG. 2 illustrates different vacuum pressures through different hatching. The electron source 110 may be evacuated by the vacuum pump 119 for an electron source and may operate at a pressure of VAC1. For example, VAC1, which is a pressure at which the electron source 110 operates, may range from 1×10⁻⁸ Pa to 1×10⁻⁷ Pa.

For example, VAC1, which is the pressure at which the electron source 110 operates, may range from 1×10⁻⁸ Pa to 1×10⁻⁷ Pa.

The beam tube 200 may be evacuated by a vacuum pump 142 for a beam tube and maintained at a pressure of VAC2. For example, VAC2 may range from 1×10⁻⁶ Pa to 1×10⁻⁵ Pa. The beam tube 200 and the electron source 110 are divided into different regions by an aperture in which an electron source orifice is formed.

A charged particle beam passes through the electron source orifice formed between the electron source 110 and the beam tube 200. Two regions of different pressures are connected through the electron source orifice, but an opening of the electron source orifice is large enough to allow the charged particle beam to pass through and has a diameter at which a pressure difference between VAC1, which is a pressure at which the electron source 110 operates, and VAC2, which is a pressure formed in the beam tube 200, may be maintained. Furthermore, the regions of the beam tube 200 and the electron source 110 may be respectively evacuated by the vacuum pump 142 for a beam tube and the vacuum pump 119 for an electron source and maintained at desired pressures.

The objective lens 500 may be evacuated by a vacuum pump 144 for an objective lens and maintained at a pressure of VAC3 of the high vacuum (HV) degree. For example, VAC3 may range from 5×10⁻⁶ Pa to 1×10⁻⁴ Pa. Two regions of the beam tube 200 and the objective lens 220 are separated by the orifice 410 for a beam tube. The orifice 410 for the beam tube has a diameter that is large enough to allow the charged particle beam B to pass through, and has a diameter at which a difference between VAC2, which is a pressure formed in the beam tube 200, and VAC3, which is a pressure formed in the objective lens 500, may be maintained. Likewise, the regions of the beam tube 200 and the objective lens 500 may be respectively evacuated by the vacuum pump 142 for a beam tube and the vacuum pump 144 for an objective lens and maintained at desired pressures.

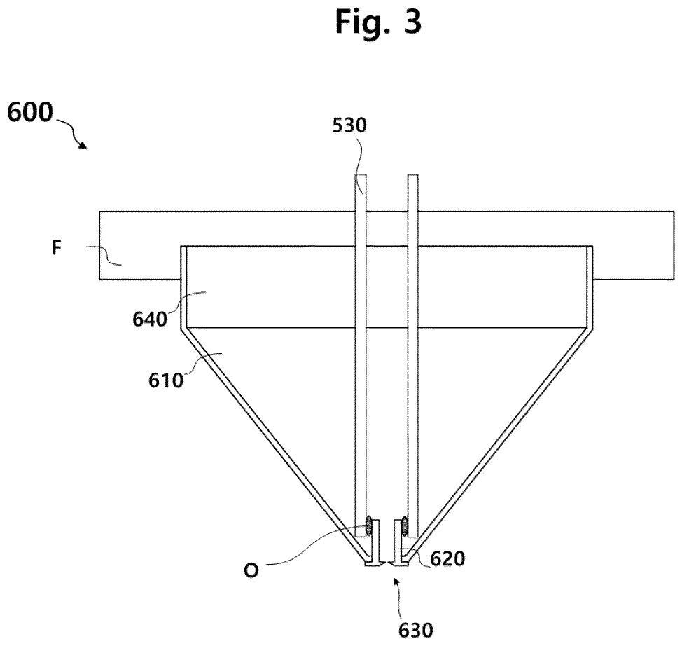

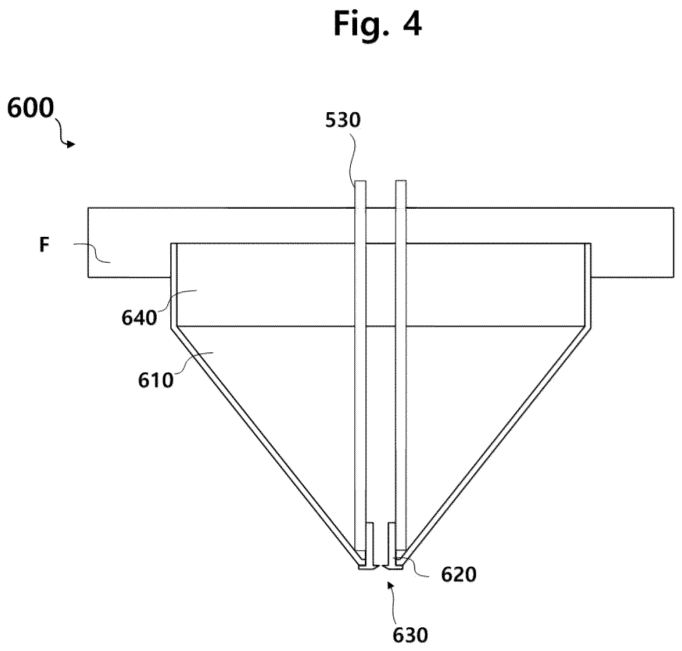

The objective lens 500 and the sample chamber C are divided into different regions by the objective lens cover 600. An orifice 630 (see FIGS. 3 and 4) formed in the objective lens cover 600 has a diameter that is large enough to allow the charged particle beam B to pass through, and has a diameter at which a pressure difference between 5×10⁻⁶ Pa to 1×10⁻⁴ Pa, which is a pressure of a HV region inside the objective lens, and 1×10⁻⁷ Pa or less, which is a pressure of an ultra-high vacuum (UHV) region inside the sample chamber C, may be maintained. The regions of the objective lens 500 and the sample chamber C may be respectively evacuated by the vacuum pump 144 for an objective lens and a sample chamber vacuum pump 146 and maintained at desired pressures. The objective lens 500 is a magnetic field type objective lens, and circulates cooling water by placing a coil that excites the lens in a normal pressure environment (indicated as atmospheric pressure, air pressure, or air) to cool the coil.

FIGS. 3 and 4 are diagrams illustrating examples of the objective lens cover 600. Referring to FIGS. 3 and 4, the objective lens cover 600 includes a conical cover 610 having a shape corresponding to an external shape of the objective lens 500, on which the objective lens 500 is mounted, and having an opening O through which a charged particle beam B passes, and an inner connection unit 620 inserted into an inside of the conical cover 610 through the opening O and having a beam path through which the charged particle beam B passes. The objective lens cover 600 of the present embodiment divides a sample chamber C that is maintained at a pressure of 1×10⁻⁷ Pa or less and the UHV degree, and an internal region of the objective lens 500 that is maintained at the HV degree of a pressure of 5×10⁻⁶ Pa to 1×10⁻⁴ Pa.

The objective lens cover 600 is made of a material, which is non-magnetic and emits little or no gas under vacuum. For example, the objective lens cover 600 is characterized by being made of one of austenitic stainless steel (Sus304, Sus316, and Sus310), aluminum (Al), and titanium (Ti). Since the objective lens cover is non-magnetic, a magnetic field generated from the objective lens, alignment, and stigma may be formed onto a path (optical axis) of an electron beam without being affected by the objective lens cover, so that the focus, deflection, and astigmatism correction of the electron beam may be performed.

The conical cover 610 is formed to correspond to an outer shape of the objective lens 500 and is coupled to the objective lens 500. Typically, the objective lens 500 is made of pure iron with a high saturation magnetic flux density, and wet plating with nickel (Ni) as a main component is performed to prevent rust and corrosion. A plating film contains many impurities, so when the plating film is placed in a vacuum atmosphere, a large amount of gas is released, making it difficult to obtain the UHV degree.

However, the objective lens cover 600 according to the present embodiment separates the objective lens 500 located therein from the sample chamber C (see FIGS. 1 and 2) maintained at the UHV degree. Therefore, the objective lens cover 600 blocks the gas generated from the plating film of the objective lens 500 from being introduced into the sample chamber C (see FIGS. 1 and 2).

Further, SEM samples are usually placed in the sample chamber maintained at the UHV degree of 10⁻³ to 10⁻⁴ Pa. The vacuum atmosphere of the sample chamber maintained at the HV degree contains many hydrocarbon compound (CₙHₙ) gases. Therefore, when an electron beam is emitted to the sample, the hydrocarbon compound gas is decomposed so that a thin film of carbide is attached on the sample, thereby contaminating the sample. Contamination of a surface of the sample is an undesirable problem in SEM observation. Since this carbon film has low secondary electron emission efficiency, the part where the electron beam is emitted when observing the sample has a low signal level and is observed as a dark region.

Under low-energy conditions of the electron beam, contamination problems are prominent. Further, when elements, chemical bonds, and molecular bonds on the surface of the sample are analyzed using an electron beam, there is a problem in that the attached carbon film covers the surface of the sample, making it difficult to obtain the original signal of the sample, and carbonized materials such as graphene and carbon nanotubes are difficult to distinguish from the attached carbon film due to contamination. Further, at the high vacuum degree of 10⁻³ to 10⁻⁴ Pa, residual gases such as water molecules, hydrogen molecules, and oxygen molecules contained in the vacuum atmosphere are adsorbed onto the surface of the sample and cover the entire surface within a time, making it difficult to analyze the sample's outermost surface.

In order to solve the above problems, in the present embodiment, a pressure of VAC4 in the sample chamber C is maintained at an ultra-low pressure of 1×10⁻⁷ Pa or less, or an UHV degree, and in the present embodiment, the sample chamber C is evacuated by the sample chamber vacuum pump 146 and maintained at the pressure of VAC4, which is an UHV degree. Further, a pressure atmosphere of the objective lens 500 and a pressure atmosphere of the sample chamber C are not mixed due to the objective lens cover 600, and an UHV atmosphere in the sample chamber C is maintained. Therefore, contamination of the sample can be prevented.

In one embodiment, the conical cover 610 extends to an outer cylinder structure 640 in the form of a cylinder, and a flange F is formed around the outer cylinder structure 640. The flange F is airtightly connected to the sample chamber C (see FIG. 1) through the metal sealing member M (see FIG. 1). In one embodiment, a surface of the flange F that faces the metal sealing member M (see FIG. 1) may be processed with a knife edge to obtain higher airtightness.

At the tip of the conical cover 610, an inner connection unit 620 that is in communication with the objective lens communication member 530 to be connected thereto is located. A diameter of an opening at the tip is 1 mm or less, and an ultra-high vacuum sample chamber and a vacuum chamber above the objective lens are differentially exhausted. As in the embodiment illustrated in FIG. 3, the inner connection unit 620 may be connected through the O-ring O to be airtightly connected to the objective lens communication member 530. Further, as in the embodiment illustrated in FIG. 4, the inner connection unit 620 may be airtightly connected to the objective lens communication member 530 through welding.

FIG. 5 is a cross-sectional view illustrating an outline of the inner connection part 620. Referring to FIGS. 3 to 5, the inner connection unit 620 includes an inner wall part 622 connected to the objective lens communication member 530 to be sealed, and an aperture part 624 having an opening O. A cross section of the inner wall part 622 may correspond to a cross section of the objective lens communication member 530. For example, when the objective lens communication member 530 has a circular cross section, the inner wall part 622 may also have a circular cross section.

The aperture part 624 has an opening 630. The opening 630 has a diameter of an opening such that the charged particle beam B (see FIG. 1) can pass through and a difference in pressure between the sample chamber C and the objective lens 500 can be maintained at least 50 times different in pressure. In the embodiment illustrated in FIG. 5, in the opening 630, a diameter r2 of an opening on the sample chamber side and a diameter r1 of an opening on the objective lens side may be different from each other. As in the illustrated example, the diameter r2 of the opening on the sample chamber side may be greater than the diameter r1 of the opening on the objective lens side. However, in the example not illustrated, the diameter r2 of the opening on the sample chamber side may be equal to or smaller than the diameter r1 of the opening on the objective lens side.

In one embodiment, the aperture part 624 and the inner wall part 622 may be welded and bonded so that no hole through which pressure is released is generated, except for the opening 630.

### Implementation Example

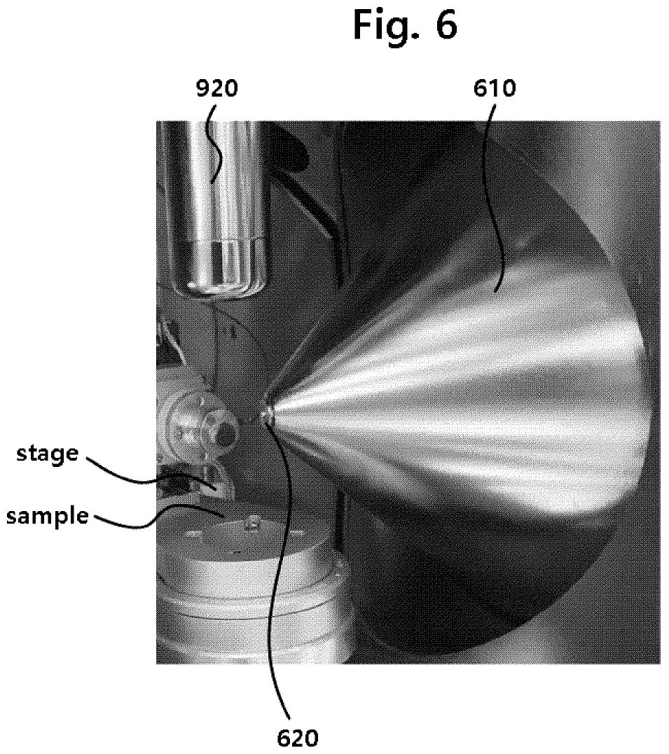

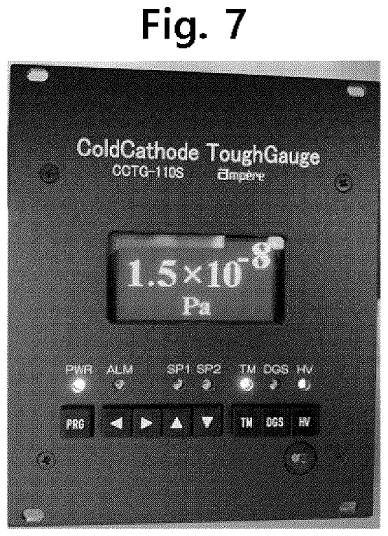

FIG. 6 is a view showing a charged particle beam apparatus 10 equipped with an objective lens cover according to an embodiment of the present invention. Referring to FIG. 6, an aperture unit 620 mounted on the conical cover 610 is illustrated, and a stage and a sample located on the stage are illustrated. Further, a secondary electron detector 920 for detecting secondary electrons is illustrated on an upper side. FIG. 7 is a view showing a pressure inside a sample chamber. FIG. 7 shows results of vacuum measurement by a cold cathode gauge placed in the sample chamber. As illustrated, it can be seen that the sample chamber is maintained at the UHV degree of 1.5×10⁻⁸ Pa.

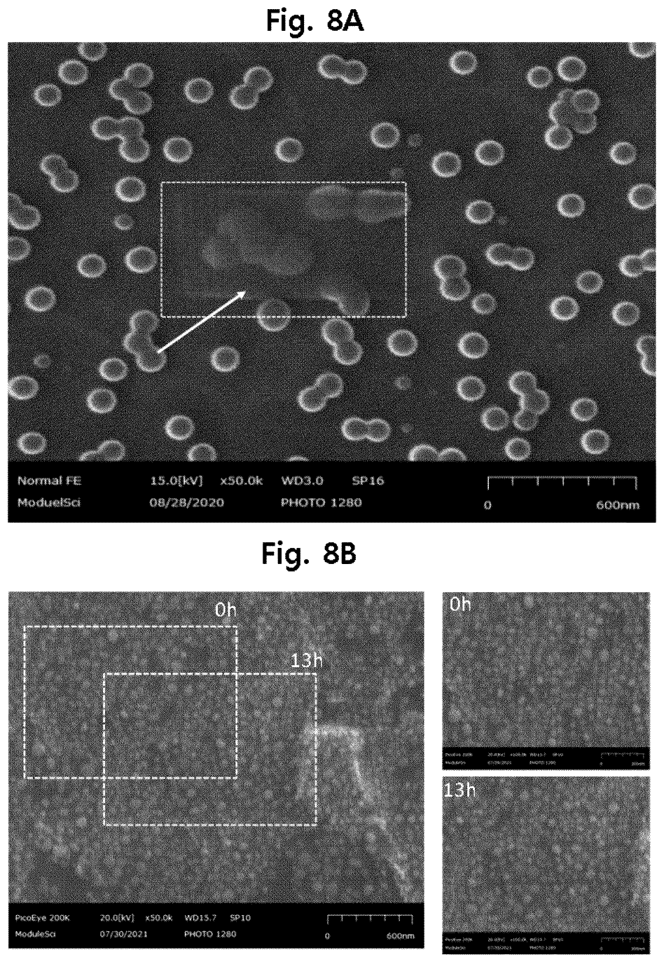

FIGS. 8A and 8B are views showing the degree of contamination of a sample according to a vacuum degree inside the sample chamber. FIG. 8A shows an image obtained with a conventional SEM device when a sample chamber was maintained at a pressure of 10⁻³ to 10⁻⁴ Pa, which corresponds to a typical HV degree. FIG. 8B shows results of setting the SEM to high magnification, irradiating the sample with electron beams continuously for 11 minutes, and then taking photographs of the sample. It can be seen that the clarity is impaired due to the attachment of contaminants as shown in white square frames. The transverse movement is caused by the drift of the electron beam or the sample.

FIG. 8B shows SEM photographs taken when the charged particle beam apparatus equipped with the objective lens cover of the present embodiment, as illustrated in FIG. 6, was used and the sample chamber was maintained at a maximum pressure of 10⁻⁸ Pa corresponding to the UHV degree. FIG. 8B shows a result obtained by comparing before and after irradiation after setting the SEM to high magnification and irradiating the sample with electron beams continuously for 13 hours. An image taken immediately before the irradiation (upper right, 0 h) and a sample photograph taken after 13 hours of irradiation (lower right, 13 h) are attached together. Unlike FIG. 8A, before and after irradiating the sample with the electron beams, it can be seen that the image taken immediately before irradiation and the image taken after 13 hours of irradiation are almost equally clear, and the sample may be identified very clearly because there are no contaminants attached to the sample. The effectiveness of the charged particle beam apparatus equipped with the objective lens cover of the present embodiment capable of maintaining a sample chamber at the UHV degree can be confirmed.

According to the present invention, it is possible to provide an objective lens cover that allows an objective lens to operate in two regions having a pressure difference of at least 50 times or more.

While the present invention has been described with reference to the embodiments illustrated in the accompanying drawings to help understanding, the embodiments should be considered in a descriptive sense only, and it should be understood by those skilled in the art that various alterations and equivalent other embodiments may be made. Therefore, the scope of the present invention should be defined by the appended claims.

What is claimed is:

1. An objective lens cover of a charged particle beam apparatus, comprising:
a conical cover having a shape corresponding to an external shape of an objective lens, on which the objective lens is mounted, and having an opening through which a charged particle beam passes; and
an inner cylindrical part inserted into an inside of the conical cover through the opening and having a beam path through which the charged particle beam passes,
wherein the objective lens cover divides at least two regions with a pressure difference of at least 50 times.

2. The objective lens cover of claim 1, wherein the conical cover and the inner cylindrical part are airtightly welded.

3. The objective lens cover of claim 1, wherein the conical cover and the inner cylindrical part are airtightly connected.

4. The objective lens cover of claim 1, wherein any one of the two regions is a sample chamber in which a sample is placed, and
the other of the two regions is an internal region of the objective lens.

5. The objective lens cover of claim 1, wherein any one of the two regions is a region maintained at an ultra-high vacuum (UHV) degree of 1×10⁻⁷ Pa or less, and
the other of the two regions is a region maintained at a high vacuum (HV) degree of 5×10⁻⁶ Pa to 1×10⁻⁴ Pa.

6. The objective lens cover of claim 1, wherein the conical cover is made of a material that does not emit gas into either of the two regions.

7. The objective lens cover of claim 1, further comprising a flange configured to extend outward from the conical cover and having a knife edge,
wherein the knife edge is coupled to a sealing member and engaged with any one of the two regions.

8. The objective lens cover of claim 1, wherein the inner cylindrical part extends to be airtightly sealed with an objective lens cylindrical part, through which the charged particle beam passes, in the objective lens.

9. The objective lens cover of claim 8, further comprising a sealing member,
wherein the sealing member connects the inner cylindrical part to the objective lens cylindrical part to be airtightly sealed.

10. A charged particle beam apparatus comprising:
a charged particle source;
one or more condenser lenses configured to focus a charged particle beam;
an objective lens configured to irradiate a sample with the charged particle beam;
a detector configured to detect secondary electrons formed from the sample;
a conical cover having a shape corresponding to an external shape of the objective lens, on which the objective lens is mounted, and having an opening through which the charged particle beam passes; and
an inner cylindrical part inserted into an inside of the conical cover through the opening and having a beam path through which the charged particle beam passes,
wherein the objective lens cover divides at least two regions with a pressure difference of at least 50 times.

11. The charged particle beam apparatus of claim 10, wherein the conical cover and the inner cylindrical part are airtightly welded.

12. The charged particle beam apparatus of claim 10, wherein the conical cover and the inner cylindrical part are airtightly connected.

13. The charged particle beam apparatus of claim 10, wherein any one of the two regions is a sample chamber in which the sample is placed, and
the other of the two regions is an internal region of the objective lens.

14. The charged particle beam apparatus of claim 13, wherein the sample chamber and the internal region of the objective lens are maintained at different pressures by separate pumps.

15. The charged particle beam apparatus of claim 10, wherein any one of the two regions is a region maintained at an ultra-high vacuum (UHV) degree of 1×10⁻⁷ Pa or less, and
the other of the two regions is a region maintained at a high vacuum (HV) degree of 5×10⁻⁶ Pa to 1×10⁻⁴ Pa.

16. The charged particle beam apparatus of claim 10, wherein the conical cover is made of a material that does not emit gas into either of the two regions.

17. The charged particle beam apparatus of claim 10, wherein the objective lens cover further includes a flange that extends outward from the conical cover and having a knife edge, and
the knife edge is coupled to a sealing member and engaged with any one of the two regions.

18. The charged particle beam apparatus of claim 10, wherein the inner cylindrical part extends to be airtightly sealed with an objective lens cylindrical part, through which the charged particle beam passes, in the objective lens.

19. The charged particle beam apparatus of claim 17, wherein the objective lens cover further includes a sealing member, and
the sealing member connects the inner cylindrical part to the objective lens cylindrical part to be airtightly sealed.
